(19) United States
(12) Patent Application Publication
(10) Pub. No.: US 2023/0144304 A1
(43) Pub. Date: May 11, 2023

(54) SEMICONDUCTOR STRUCTURE

(71) Applicant: Powerchip Semiconductor Manufacturing Corporation, Hsinchu (TW)

(72) Inventors: Chien-Le Chang, Hsinchu County (TW); Chang-Chin Ho, Hsinchu City (TW); Yong-Kang Jiang, Hsinchu City (TW)

(73) Assignee: Powerchip Semiconductor Manufacturing Corporation, Hsinchu (TW)

(21) Appl. No.: 17/674,843

(22) Filed: Feb. 18, 2022

(30) Foreign Application Priority Data
Nov. 11, 2021 (TW) 110142012

(51) Int. Cl. H01L 29/423; H01L 29/417

(52) U.S. Cl. CPC H01L 29/4236; H01L 29/41775

(57) ABSTRACT

The present disclosure provides a semiconductor structure including a substrate, a first gate structure, and a second gate structure. The substrate includes at least one first trench group and at least one second trench group spaced apart from each other. The first trench group includes first trenches spaced apart from each other in a first direction and extending in a second direction other than the first direction. The second trench group includes second trenches spaced apart from each other in the second direction and extending in the first direction. The first gate structure is disposed in each of the first trenches and extends in the second direction. The second gate structure is disposed in each of the second trenches and extends in the first direction.

### CROSS-REFERENCE TO RELATED APPLICATION

This application claims the priority benefit of Taiwan application serial no. 110142012, filed on Nov. 11, 2021. The entirety of the above-mentioned patent application is hereby incorporated by reference herein and made a part of this specification.

### BACKGROUND OF THE INVENTION

### 1. Field of the Invention

The invention relates to a semiconductor structure, and more particularly, to a trench gate metal-oxide-semiconductor (MOS) structure.

### 2. Description of Related Art

A trench gate MOS structure usually applies in power switch devices, such as power supplies, rectifiers, low-voltage motor controllers, or so forth devices. The trench gate MOS structure is often resorted to a design of vertical structure to enhance the device density. For example, drain terminal is formed on the back-side of a chip, and each source region and each gate are formed on the front-side of the chip. The drain regions of the transistors are connected in parallel so as to endure a considerable large current.

In general, the working loss of the trench gate MOS structure may be divided into a switching loss and a conducting loss, wherein the switching loss caused by the input capacitance is going up as the operation frequency is increased. The input capacitance includes a gate-to-source capacitance C_{gs} and a gate-to-drain capacitance C_{gd}. In the known practices, the gate-to-drain capacitance C_{gd} may be reduced by forming a shield gate below the gate so as to improve the switching loss. However, as the pitch of a device is shrunk down continuously, trenches, formed in a wafer and having high aspect ratios, would cause the degree of the warpage of the wafer being too high to proceed subsequent processes. That is, when the degree of the warpage of the wafer is considered, the depths of the trenches are limited and cannot be increased arbitrarily.

### SUMMARY OF THE INVENTION

The present invention provides a semiconductor structure in which a substrate is designed to include first and second trenches extending in different directions to improve the stress distribution of the substrate and thus the degree of warpage of a wafer including the substrate can be decreased.

An embodiment of the present invention provides a semiconductor structure including a substrate, a first gate structure, and a second gate structure. The substrate includes at least one first trench group and at least one second trench group spaced apart from each other. The first trench group includes first trenches spaced apart from each other in a first direction and extending along a second direction different from the first direction. The second trench group includes second trenches spaced apart from each other in the second direction and extending along the first direction. The first gate structure is disposed in each first trench and extending along the second direction. The second gate structure is disposed in each second trench and extending along the first direction.

In some embodiments, the at least one first trench group includes first trench groups, and the second trench group is arranged between the two neighboring first trench groups.

In some embodiments, the at least one first trench group includes first trench groups, and the at least one second trench group includes second trench groups. The first trench groups and the second trench groups are arranged alternatively in the first direction and/or in the second direction.

In some embodiments, the semiconductor structure further includes a gate pad and a gate line. The gate pad is disposed on the substrate. The gate line is disposed on the substrate and electrically connected the first gate structure and the second gate structure to the gate pad. The gate line includes first segments extending in the first direction and second segments extending in the second direction. The two neighboring first segments are connected through the second segment, and the two neighboring second segments are connected through the first segment.

In some embodiments, two opposite ends of the first gate structure in the second direction are connected to the first segments of the gate line, respectively, and two opposite ends of the second gate structure in the first direction are connected to the second segments of the gate line, respectively.

In some embodiments, the semiconductor structure further includes a source pad disposed on the substrate and covering the first gate structure and the second gate structure. The source pad includes first slits extending along the first direction and second slits extending along the second direction.

In some embodiments, some first slits among the first slits are interconnected with some second slits among the second slits, and some other first slits among the first slits are not interconnected with some other second slits among the second slits.

In some embodiments, the gate pad and the gate line do not overlap with the source pad in a direction perpendicular to the substrate.

In some embodiments, the first segments overlap the first slits in a direction perpendicular to the substrate, and the second segments overlap the second slits in the direction perpendicular to the substrate.

In some embodiments, the source pad includes a first portion covering the first gate structure and a second portion covering the second gate structure. The first portion of the source pad includes first sidewalls extending in the first direction and opposite to each other, and the first segments extend along the first sidewalls when viewing from top. The second portion of the source pad includes second sidewalls extending in the second direction and opposite to each other, and the second segments extend along the second sidewalls when viewing from top.

In some embodiments, the first direction and the second direction are substantially parallel to a top surface of the substrate, and the first direction is substantially perpendicular to the second direction.

In some embodiments, depths of the first trenches and the second trenches are in a range of about 7.1 μm to about 8.5 μm.

Based on the above, in the above semiconductor structure, the substrate is designed to include first and second trenches extending in different directions to improve the stress distribution of the substrate and thus the degree of warpage of a wafer including the substrate can be decreased. Moreover, the depths of the trenches (e.g., first trenches and second trenches) formed in the substrate can further be increased to enhance the break down voltage of the semiconductor structure.

To make the above features and advantages of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic top view illustrating a semiconductor structure in accordance with an embodiment of the present invention.

FIG. 2 is a schematic diagram illustrating the relationship between depths of trenches and radiuses of curvature of wafers.

FIG. 3A is a schematic diagram of a wafer including a semiconductor structure viewed from a viewing angle according to an embodiment of the present invention.

FIG. 3B is a schematic diagram of a wafer including a semiconductor structure viewed from another viewing angle according to an embodiment of the present invention.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

The invention will be described more comprehensively below with reference to the drawings for the embodiments. However, the invention may also be implemented in different forms rather than being limited by the embodiments described in the invention. Thicknesses of layer and region in the drawings are enlarged for clarity. The same reference numbers are used in the drawings and the description to indicate the same or like parts, which are not repeated in the following embodiments.

It will be understood that when an element is referred to as being “on” or “connected” to another element, it may be directly on or connected to the other element or intervening elements may be present. If an element is referred to as being “directly on” or “directly connected” to another element, there are no intervening elements present. As used herein, “connection” may refer to both physical and/or electrical connections, and “electrical connection” or “coupling” may refer to the presence of other elements between two elements. As used herein, “electrical connection” may refer to the concept including a physical connection (e.g., wired connection) and a physical disconnection (e.g., wireless connection).

As used herein, “about”, “approximately” or “substantially” includes the values as mentioned and the average values within the range of acceptable deviations that can be determined by those of ordinary skill in the art. Consider to the specific amount of errors related to the measurements (i.e., the limitations of the measurement system), the meaning of “about” may be, for example, referred to a value within one or more standard deviations of the value, or within ±30%, ±20%, ±10%, ±5%. Furthermore, the “about”, “approximate” or “substantially” used herein may be based on the optical property, etching property or other properties to select a more acceptable deviation range or standard deviation, but may not apply one standard deviation to all properties.

The terms used herein are used to merely describe exemplary embodiments and are not used to limit the present disclosure. In this case, unless indicated in the context specifically, otherwise the singular forms include the plural forms.

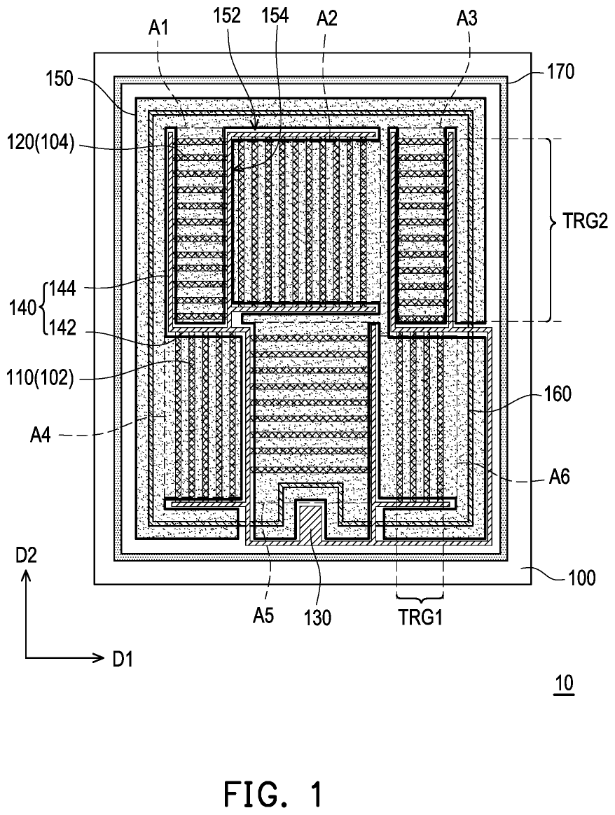

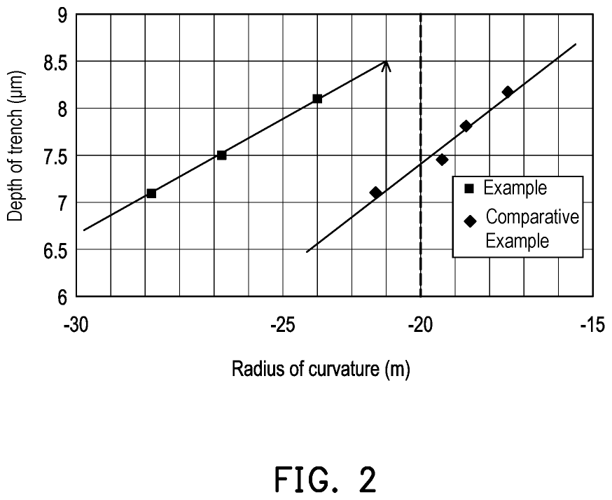

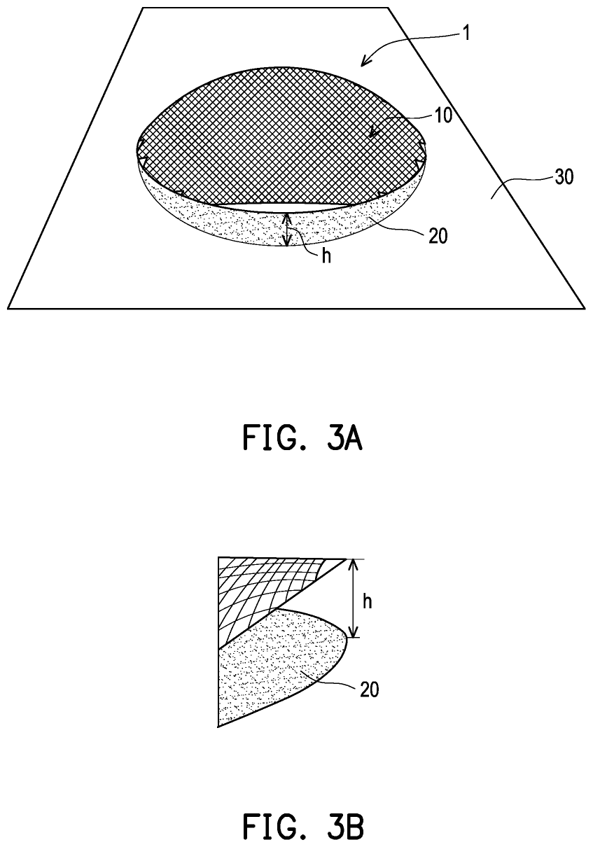

FIG. 1 is a schematic top view illustrating a semiconductor structure in accordance with an embodiment of the present invention. FIG. 2 is a schematic diagram illustrating the relationship between depths of trenches and radiuses of curvature of wafers. FIG. 3A is a schematic diagram of a wafer including a semiconductor structure viewed from a viewing angle according to an embodiment of the present invention. FIG. 3B is a schematic diagram of a wafer including a semiconductor structure viewed from another viewing angle according to an embodiment of the present invention.

Referring to FIG. 1, a semiconductor structure 10 includes a substrate 100, a first gate structure 110, and a second gate structure 120.

The substrate 100 may include a doped semiconductor substrate and an epitaxial layer formed on the doped semiconductor substrate. In some embodiments, the doped semiconductor substrate and the epitaxial layer may have the same conductive type (e.g., N-type). In some embodiments, the doped semiconductor substrate may be a heavily doped N-type silicon substrate. As such, in the case where the semiconductor structure 10 is a trench gate MOS structure, the heavily doped N-type silicon substrate may be a drain electrode of the trench gate MOS structure, but is not limited thereto. In some embodiments, a drain electrode (not shown) of a trench gate MOS structure may be disposed on a bottom surface (e.g., a surface being opposite to a top surface of the substrate 100 in the subsequent description) of the substrate 100. The epitaxial layer may be a lightly doped N-type epitaxial layer, and a method for forming the lightly doped N-type epitaxial layer may include an epitaxy growth process which is performed on the doped semiconductor substrate.

The substrate 100 includes at least one first trench group TRG1 and at least one second trench group TRG2 spaced apart from each other. The first trench group TRG1 includes first trenches 102 spaced apart from each other in a first direction D1 and extending along a second direction D2 different from the first direction D1. The second trench group TRG2 includes second trenches 104 spaced apart from each other in the second direction D2 and extending along the first direction D1. As such, since the substrate 100 includes the first trenches 102 and the second trenches 104 extending in different directions, the stress distribution of the substrate 100 can be improved and thereby decreasing the degree of warpage of a wafer (e.g., the wafer 1 shown in FIG. 3A) including the substrate 100. Moreover, when the stress distribution of the substrate 100 is improved, depths of the first trenches 102 and second trenches 104 can be further increased to enhance the break down voltage of the semiconductor structure 10. In some embodiments, the depths of the first trenches 102 and the second trenches 104 may be in a range of about 7.1 μm to about 8.5 μm. In some embodiments, the first direction D1 and the second direction D2 are substantially parallel to the top surface of the substrate 100. In some embodiments, the first direction D1 is substantially perpendicular to the second direction D2.

In some embodiments, the first trenches 102 and the second trenches 104 may extend from the top surface of the substrate 100 to the inside of the substrate 100. In some embodiments, lengths of the first trenches 102 extending in the second direction D2 may be different from lengths of the second trenches 104 extending in the first direction D1. A quantity of the first trenches 102 in the first trench group TRG1 and a quantity of the second trenches 104 in the second trench group TRG2 may be adjusted according to the design, the present invention is not limited thereto. A pitch between the two neighboring first trenches 102 and a pitch between the two neighboring second trenches 104 can be adjusted according to the design, the present invention is not limited thereto.

In some embodiments, the at least one first trench group TRG1 may include a plurality of first trench groups TRG1, and the second trench group TRG2 may be arranged between the two neighboring first trench groups. In some alternative embodiments, the at least one second trench group TRG2 may include a plurality of second trench groups TRG2, and the first trench group TRG1 may be arranged between the two neighboring second trench groups TRG2. In some other embodiments, as shown in FIG. 1, the at least one first trench group TRG1 may include a plurality of first trench groups TRG1, and the at least one second trench group TRG2 may include a plurality of second trench groups TRG2, wherein the first trench groups TRG1 and the second trench groups TRG2 may be arranged alternatively in the first direction D1 and/or in the second direction D2.

FIG. 1 exemplarily shows three first trench groups TRG1 and three second trench groups TRG2, and these first trench groups TRG1 and these second trench groups TRG2 may be arranged alternatively in the first direction D1 and/or in the second direction D2. In some embodiments, the substrate 100 may include regions (e.g., regions A2, A4, and A6 shown in FIG. 1) where the first trench groups TRG1 are formed and regions (e.g., regions A1, A3, and A5 shown in FIG. 1) where the second trench groups TRG2 are formed. The shape, size, quantity and arrangement of the regions A1-A6 shown in FIG. 1 can be adjusted according to the degree of warpage of the wafer.

The first gate structure 110 is disposed in each of the first trenches 102 and extends along the second direction D2. The first gate structure 110 may include an insulation layer such as an oxide and a conductive layer such as a doped polysilicon. In some embodiments, the conductive layer of the first gate structure 110 may be spaced apart from the substrate 100 by the insulation layer disposed between the conductive layer and the substrate 100.

The second gate structure 120 is disposed in each of the second trenches 104 and extends along the first direction D1. The second gate structure 120 may include an insulation layer such as an oxide and a conductive layer such as a doped polysilicon. In some embodiments, the conductive layer of the second gate structure 120 may be spaced apart from the substrate 100 by the insulation layer disposed between the conductive layer and the substrate 100.

In some embodiments, the semiconductor structure 10 may further include a gate pad 130 and a gate line 140. The gate pad 130 may be disposed on the substrate 100. The gate line 140 may be disposed on the substrate 100 and electrically connects the first gate structure 110 and the second gate structure 120 to the gate pad 130.

A material of the gate pad 130 may include a conductive material such as a metal material (e.g., Al or W), a conductive metal nitride (e.g., WN, TiSiN, WSiN, TiN, or TaN), or a combination thereof. A material of the gate line 140 may include a conductive material such as a metal material (e.g., Al or W), a conductive metal nitride (e.g., WN, TiSiN, WSiN, TiN, or TaN), or a combination thereof. The gate line 140 may be electrically connected to the first gate structure 110 and the second gate structure 120 through contact plugs (now shown). In some embodiments, the material of the gate line 140 may be different from the materials of the conductive layers of the first gate structure 110 and the second gate structure 120.

In some embodiments, the gate line 140 may include first segments 142 extending in the first direction D1 and second segments 144 extending in the second direction D2. In some embodiments, the two neighboring first segments 142 may be connected through the second segment 144. In some embodiments, the two neighboring second segments 144 may be connected through the first segment 142. In some embodiments, the opposite ends of the first gate structure 110 in the second direction D2 are connected to the first segments 142 of the gate line 140, respectively. In some embodiments, the opposite ends of the second gate structure 120 in the first direction D1 are connected to the second segments 144 of the gate line 140.

In some embodiments, the semiconductor structure 10 may further include a source pad 150 disposed on the substrate 100 and covering the first gate structure 110 and the second gate structure 120. In some embodiments, the gate pad 130 and the gate line 140 may not overlap with the source pad 150 in a direction (e.g., a direction perpendicular to the first direction D1 and the second direction D2). In some embodiments, the source pad 150 may include first portions (e.g., portions located on the regions A2, A4, and A6 of the substrate 100) covering the first gate structure 110 and second portions (e.g., portions located on the regions A1, A3, and A5 of the substrate 100) covering the second gate structure 120. The first portions of the source pad 150 may include first sidewalls extending in the first direction D1 and opposite to each other in the second direction D2. The first segments 142 of the gate line 140 may extend along the first sidewalls of the first portions of the source pad 150 when viewing from top. The second portions of the source pad 150 may include second sidewalls extending in the second direction D2 and opposite to each other in the first direction D1. The second segments 144 of the gate line 140 may extend along the second sidewalls of the second portions of the source pad 150 when viewing from top.

The source pad 150 may include first slits 152 extending in the first direction D1 and second slits 154 extending in the second direction D2. In some embodiments, some first slits 152 among the first slits 152 may be interconnected with some second slits 154 among the second slits 154, and some other first slits 152 among the first slits 152 may not be interconnected with some other second slits 154 among the second slits 154. In some embodiments, the first segments 142 of the gate line 140 overlap the first slits 152 of the source pad 150 in a direction perpendicular to the substrate 100. In some embodiments, the second segments 144 of the gate line 140 overlap the second slits 154 of the source pad 150 in the direction perpendicular to the substrate 100.

A material of the source pad 150 may include a conductive material such as a metal material (e.g., Al or W), a conductive metal nitride (e.g., WN, TiSiN, WSiN, TiN, or TaN), or a combination thereof.

In some embodiments, the substrate 100 may include a guard ring 160 embedded in the substrate 100. The guard ring 160 may surround the first gate structure 110 and the second gate structure 120. In some embodiments, the guard ring 160 may surround the gate pad 130 and the gate line 140 when viewing from top. FIG. 1 only shows one guard ring 160 as an exemplary example for description. The quantity of the guard ring 160 can be adjusted according to the voltage applied to the semiconductor structure 10. For example, when the voltage applied to the semiconductor structure 10 is higher, the quantity of the guard ring 160 surrounding the first gate structure 110 and the second gate structure 120 may be increased, but the invention is not limited thereto.

In some embodiments, the substrate 100 may include a seal ring 170 embedded in the substrate 100. The seal ring 170 may surround the first gate structure 110, the second gate structure 120, and the guard ring 160. In some embodiments, the seal ring 170 may surround the gate pad 130, the gate line 140, and the source pad 150 when viewing from top. The seal ring 170 may be electrically floating, and the material of the seal ring 170 may include a insulation material, but is not limited thereto.

Referring to FIG. 2, the Example was a wafer (e.g., wafer 1 shown in FIG. 3A) including the semiconductor structure 10. Namely, the Example had trenches designed to be extending in different directions. The Comparative Example was a wafer including a general semiconductor structure. Namely, the Comparative Example had trenches designed to be extending in the same direction. The vertical axis of FIG. 2 was the depth of the trench, and the horizontal axis of FIG. 2 was the radius of curvature of the wafer before performing a backside grinding process or a backside metallization process (e.g., the radius of curvature of the wafer when completing the source/drain contact). In general, the closer the radius of curvature is to 0, the greater the degree of warpage of the wafer, and the negative value of the radius of curvature indicates that the downward surface of the wafer is a concave surface (e.g., wafer 1 shown in FIG. 3A). When completing the process for forming the source/drain contacts, the radius of curvature of the wafer must be less than about −20 m. If the radius of curvature is higher than the described limit value, the warpage of the wafer would be too high to proceed the subsequent processes. From FIG. 2, even if the depth of the trench of the Example reached 8.2 μm, the radius of curvature of the wafer was still less than −20 m (e.g., about −23 m). However, when the depth of the trench of the Comparative Example was about 7.5 μm, the radius of curvature of the Comparative Example was already greater than −20 m (e.g., about −19.4 m). From here, in the case where the radius of curvature of the Example was identical to the radius of curvature of the Comparative Example, the depth of the trench of the Example was about 1.5 μm deeper than the depth of the trench of the Comparative Example. In some embodiments, some processes before forming the source/drain contacts, such as processes for forming a gate electrode or processes for forming an oxide layer in the trench, the radius of curvature of the wafer of the Embodiment was less than −20 m.

The wafer 1 shown in FIG. 3A and FIG. 3B was a wafer after performing the backside grinding process or the backside metallization process. The Wafer 1 on the lining paper 20 was placed on the flat platform 30 for measurement. The height h was a maximum distance measuring between the lining paper 20 and the wafer 1 in a direction perpendicular to the platform 30 (e.g., the maximum distance between the wafer 1 and the lining paper 20 at the edge). The greater the height h was, the greater the degree of warpage of the wafer 1 exhibited, so the height h can be also referred to the warpage height.

In Table 1, the Examples 1 and 2 were wafers including the semiconductor structures 10 (e.g., wafer 1 shown in FIG. 3A). Namely, the Examples 1 and 2 had trenches designed to be extending in different directions. The Comparative Example 1 was a wafer including a general semiconductor structure. Namely, the Comparative Example 1 had trenches designed to be extending in the same direction.

TABLE 1

| | Depths of the trenches | warpage height (h) |
|---|---|---|
| Example 1 | 7.1 μm | 18 mm |
| Example 2 | 8.2 μm | 20 mm |
| Comparative Example 1 | 6.7 μm | 19 mm |

From Table 1, under the same warpage height, the depths of the trenches in the semiconductor structure 10 can be increased by about 1 μm as compared to the general semiconductor structure and thereby having a better breakdown voltage.

Based on the above, in the above semiconductor structure of the embodiments, the substrate is designed to include first and second trenches extending in different directions to improve the stress distribution of the substrate and thereby decreasing the degree of warpage of the wafer including the substrate. Moreover, the depths of the trenches (e.g., first trenches and second trenches) formed in the substrate can be further increased to enhance the break down voltage of the semiconductor structure.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A semiconductor structure, comprising:
a substrate comprising at least one first trench group and at least one second trench group spaced apart from each other, wherein the first trench group comprises first trenches spaced apart from each other in a first direction and extending along a second direction different from the first direction, and the second trench group comprises second trenches spaced apart from each other in the second direction and extending along the first direction;
a first gate structure disposed in each first trench and extending along the second direction; and
a second gate structure disposed in each second trench and extending along the first direction.

2. The semiconductor structure of claim 1, wherein the at least one first trench group comprises first trench groups, and the second trench group is arranged between the two neighboring first trench groups.

3. The semiconductor structure of claim 1, wherein the at least one first trench group comprises first trench groups, the at least one second trench group comprises second trench groups, and the first trench groups and the second trench groups are arranged alternatively in the first direction and/or in the second direction.

4. The semiconductor structure of claim 1, further comprising:
a gate pad disposed on the substrate; and
a gate line disposed on the substrate and electrically connected the first gate structure and the second gate structure to the gate pad,
wherein the gate line comprises first segments extending in the first direction and second segments extending in the second direction, the two neighboring first segments are connected through the second segment, and the two neighboring second segments are connected through the first segment.

5. The semiconductor structure of claim 4, wherein two opposite ends of the first gate structure in the second direction are connected to the first segments of the gate line, respectively, and two opposite ends of the second gate structure in the first direction are connected to the second segments of the gate line, respectively.

6. The semiconductor structure of claim 4, further comprising:
a source pad disposed on the substrate and covering the first gate structure and the second gate structure, wherein the source pad comprises first slits extending along the first direction and second slits extending along the second direction.

7. The semiconductor structure of claim 6, wherein some first slits among the first slits are interconnected with some second slits among the second slits, and some other first slits among the first slits are not interconnected with some other second slits among the second slits.

8. The semiconductor structure of claim 6, wherein the gate pad and the gate line do not overlap the source pad in a direction perpendicular to the substrate.

9. The semiconductor structure of claim 6, wherein the first segments overlap the first slits in a direction perpendicular to the substrate, and the second segments overlap the second slits in the direction perpendicular to the substrate.

10. The semiconductor structure of claim 6, wherein the source pad comprising a first portion covering the first gate structure and a second portion covering the second gate structure,
wherein the first portion of the source pad comprises first sidewalls extending in the first direction and opposite to each other, and the first segments extend along the first sidewalls when viewing from top,
wherein the second portion of the source pad comprises second sidewalls extending in the second direction and opposite to each other, and the second segments extend along the second sidewalls when viewing from top.

11. The semiconductor structure of claim 1, wherein the first direction and the second direction are substantially parallel to a top surface of the substrate, and the first direction is substantially perpendicular to the second direction.

12. The semiconductor structure of claim 1, wherein depths of the first trenches and the second trenches are in a range of about 7.1 μm to about 8.5 μm.
